(19) United States
(12) Patent Application Publication
(10) Pub. No.: US 2008/0067647 A1
(43) Pub. Date: Mar. 20, 2008

(54) SEMICONDUCTOR DEVICE

(75) Inventor: Koichi Fukuda, Barkeley, CA (US)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/854,808

(22) Filed: Sep. 13, 2007

(30) Foreign Application Priority Data
Sep. 14, 2006 (JP) 2006-249274

(51) Int. Cl. H01L 23/495

(52) U.S. Cl. 257/676; 257/E23.031

(57) ABSTRACT

A semiconductor device comprises: a semiconductor chip that is sealed in a package; and a lead that is connected to a power supply voltage source, wherein the semiconductor chip includes a boost converter including: a switch that controls a connection between a first terminal connected to the lead and a second terminal connected to a ground based on a clock signal; a rectifier having an anode terminal connected to the lead; and a capacitor connected between a cathode terminal of the rectifier and the ground.

### CROSS-REFERENCE TO RELATED APPLICATIONS

This application is based upon and claims the benefit of priority from Japanese Patent Application No. 2006-249274, filed Sep. 14, 2006, the entire contents of which are incorporated herein by reference.

### BACKGROUND OF THE INVENTION

One embodiment of the invention relates to a semiconductor device having a booster which generates, inside a chip, a potential that is higher than a power supply voltage.

For example, in nonvolatile semiconductor storage devices, a voltage that is higher than a power supply voltage (hereinafter referred to as Vcc) is necessary in each operation such as data writing, erasing, and reading. Therefore, they have a booster for generating a high voltage by boosting Vcc.

Although at present a power supply voltage of 3.3 V is still the mainstream, the proportion of products whose power supply voltages are 1.8 V is increasing gradually. As the market of portable devices expands, the market of products that are compatible with power supply voltages that are lower than 1.8 V will expand in the future. For example, in NAND flash memories, in writing to memory cells, a voltage of about 20 V is necessary for selected cells and a voltage of about 10 V is necessary for unselected cells. Furthermore, a voltage of about 20 V is necessary for erasing of memory cells and a voltage of about 5 V is necessary for reading from memory cells. All of these voltages are generated by a booster.

A circuit type called “charge pump” is widely employed in such boosters. In one exemplary charge pump, unit booster each consisting of a capacitor, a diode, etc. are arranged in series in multiple stages. A pulse voltage is applied to one terminal of each capacitor and charge is transferred to the next stage every clock cycle. The voltage of a capacitive load is boosted in this manner. There is another type of charge pump called “double voltage rectification type” in which plural parallel-connected capacitors are charged up and then their connection is changed to a series connection, whereby a high voltage is obtained.

However, in conventional charge pump boosters, problems arise when a large boost ratio is required. That is, the number of unit boosters each consisting of a capacitor, a diode, etc. increases, the area for the booster increases accordingly, and the boost efficiency decreases.

To solve the above problems, a configuration for increasing the boost efficiency is employed in which a boost converter booster consisting of an inductor, a rectifier (or a diode element), a capacitor, etc. is provided upstream of a multi-stage, charge pump booster. The inductor is provided by using an external inductor component, by mounting an inductor component on a chip, or by forming a spiral interconnection layer, for example, in a chip as an inductor.

However, in the method of using an external inductor component or mounting an inductor component on a chip, an inductor component needs to be implemented outside of a chip, which raises a problem that the cost is increased due to addition of an inductor implementing process and a cost of the inductor component. The method of forming a spiral interconnection layer, for example, in a chip as an inductor has problems that not only the number of processes but also the circuit area increase (see WO-2004-025730).

### SUMMARY OF THE INVENTION

One of objects of the present invention is to provide a semiconductor device having a booster which is low in cost, small in area, and high in boost efficiency.

According to an aspect of the present invention, there is provided A semiconductor device comprising: a semiconductor chip that is sealed in a package; and a lead that is connected to a power supply voltage source, wherein the semiconductor chip includes a boost converter including: a switch that controls a connection between a first terminal connected to the lead and a second terminal connected to a ground based on a clock signal; a rectifier having an anode terminal connected to the lead; and a capacitor connected between a cathode terminal of the rectifier and the ground.

### BRIEF DESCRIPTION OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary partially sectional side view schematically showing a semiconductor device which includes a boost converter booster circuit according to a first embodiment of the present invention.

FIG. 2 is an exemplary see-through plan view schematically showing the semiconductor device which includes the boost converter booster circuit according to the first embodiment of the invention.

FIG. 3 shows the boost converter booster circuit according to the first embodiment of the invention.

FIG. 4 shows a frequency vs. inductance characteristic that is obtained by using an iron-nickel alloy Alloy 42, which is widely used as a material of TSOP leads.

FIG. 5(a) shows an exemplary lead shape in which the lead is bent to increase the inductance, FIG. 5(b) shows a zigzagged lead shape, and FIG. 5(c) shows a lead structure in which plural leads are connected to each other by a bonding wire and an interconnection.

FIG. 6 is an exemplary partially sectional side view schematically showing a semiconductor device which includes a boost converter booster circuit according to a second embodiment of the invention.

FIG. 7 is an exemplary see-through plan view schematically showing the semiconductor device which includes the boost converter booster circuit according to the second embodiment of the invention.

FIG. 8 shows the configuration of an exemplary Dickson-type charge pump booster circuit.

FIG. 9 shows the configuration of a boost converter booster circuit.

FIGS. 10(A) and 10(B) show waveforms of a current and a voltage appearing in the boost converter booster circuit of FIG. 9.

FIG. 11 is an exemplary partially sectional side view schematically showing a semiconductor device which includes a boost converter booster circuit according to a variant embodiment of the invention.

FIG. 12(A) and (B) are exemplary partially sectional side views schematically showing a semiconductor device which includes a boost converter booster circuit according to other variant embodiments of the invention.

### DETAILED DESCRIPTION OF THE PREFERRED EMBODIMENTS

Preferred embodiments of the present invention will be hereinafter described in detail with reference to the drawings. However, the invention can be practiced in many different forms and should not be construed as being restricted by the disclosures of the following embodiments.

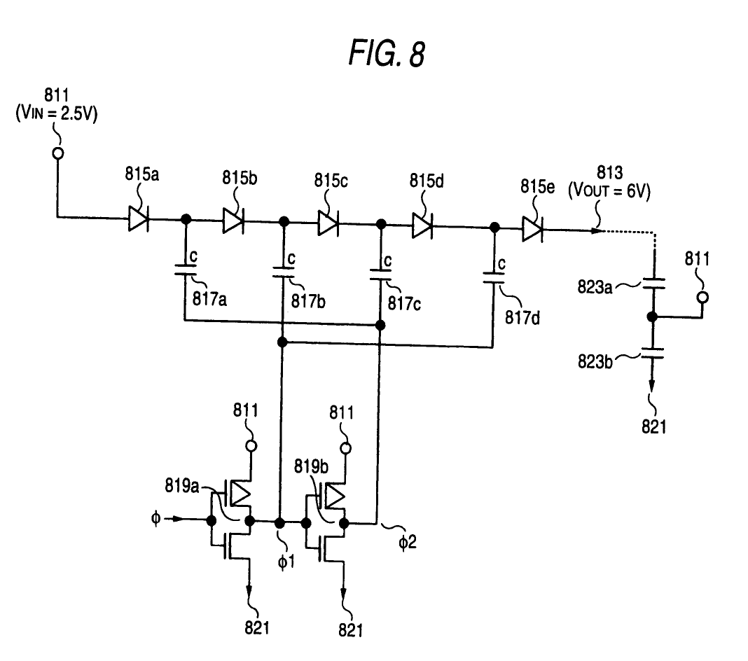

FIG. 8 shows the configuration of an exemplary Dickson-type charge pump booster circuit. A description will be made of a 4-stage charge pump circuit which is configured so as to be able to generate an output voltage (boosted voltage) of about 6 V from a supply voltage of 2.5 V.

In this example, a node 811 is connected to a power source (Vin=2.5 V) and an output voltage (Vout=6V) is supplied to the load side from a node 813. A series connection of five diode elements 815a-815e is connected between the nodes 811 and 813. All the diode elements 815a-815e are in the forward direction. A first electrode of each of pumping capacitors 817a-817d is connected to the connecting point of the cathode terminal of one of adjoining diode elements and the anode terminal of the other. In this example, the pumping capacitors 817a-817d have the same size (capacitance C). In the pumping capacitors 817a-817d, second electrodes of the pumping capacitors 817b and 817d are supplied with a first clock signal φ1, and second electrodes of the pumping capacitors 817a and 817c are supplied with a second clock signal φ2. The first clock signal φ1 is generated by a CMOS inverter circuit 819a to which a rectangular clock signal φ is input, and the second clock signal φ2 is generated by a CMOS inverter circuit 819b to which the first clock signal φ1 is input. On the other hand, a series connection of two capacitors 823a and 823b (two stages of capacitors) is connected between the output voltage node 813 and a ground potential 821. The external power source Vin (=2.5 V) is connected to the connecting point of the capacitors 823a and 823b.

The capacitor 823a is a power supply decoupling capacitor which is provided as an output load. Usually, a decoupling capacitor is provided between the output voltage node 813 and the ground potential 821. However, in this example, A different measure is taken in which the capacitor 823a is provided between the output voltage node 813 and the node 811. In general, a power supply decoupling capacitor is a MOS capacitor. This measure makes it possible to lower the breakdown voltage that is required for a gate oxide film (which is 6 V or more unless this measure is taken) to 3.5 V (=6.0 V−2.5 V). The capacitor (decoupling capacitor) 823b is provided between the ground potential 821 and the node 811 to which the external power source is connected. This allows the output voltage node 813 to be coupled strongly to the ground potential 821 via the capacitors 823a and 823b. As a result, noise in the output voltage is reduced and the output voltage is made stable.

In the above charge pump booster circuit, the unit circuits each consisting of a pumping capacitor and a diode element are arranged in series in multiple stages. A pulse bias voltage is applied to one terminal of each capacitor and charge is transferred to the next stage every clock cycle. The voltage of the capacitive load is increased in this manner.

However, in the charge pump booster circuit of FIG. 8, the boosted voltage per unit circuit is the power supply voltage minus the diode forward voltage drop. Therefore, if the power supply voltage is decreased to about 1 V, the diode voltage drop becomes dominant and the voltage can not be boosted. If low power supply voltages come to be used widely as a result of device scaling, booster circuits having the charge pump configuration will no longer be efficient. As the number of stages increases to raise the boost ratio and to get the same boosted voltage, the circuit area increases and the boost efficiency decreases. For example, a voltage of about 20 V is necessary as a writing/erasing voltage of NAND flash memories. To attain boosting to such a desired voltage from a low power supply voltage, a very large number of stages of unit circuits are necessary. The circuit area increases and the boost efficiency decreases.

In view of the above, according to the invention, a boost converter booster circuit, which is higher in boost efficiency than a charge pump booster circuit, is provided upstream of the above multi-stage charge pump booster circuit; that is, it is provided as a kind of external power source connected to the node 811 shown in FIG. 8.

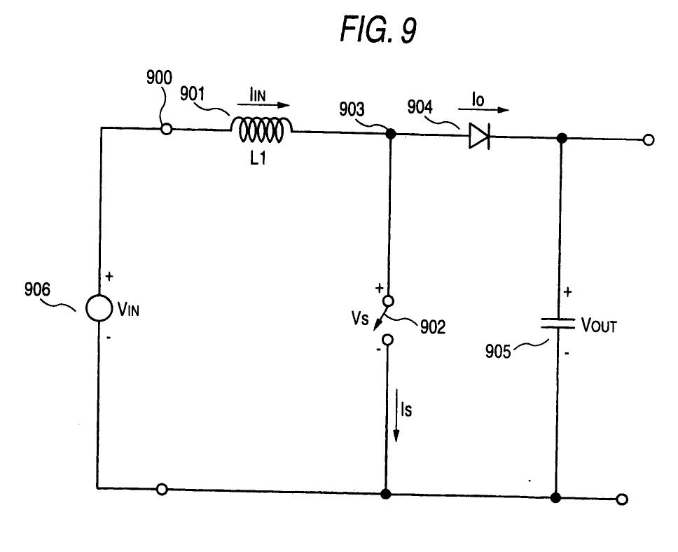

Next, the boost converter booster circuit will be described. FIG. 9 shows the configuration of an exemplary boost converter booster circuit which operates in a non-continuous mode.

When a switch 902 is closed, a current flows from a power source (Vin) 906 to an inductor 901 and magnetic energy is stored in the inductor 901. When the switch 902 is then opened, because of the stored magnetic energy, a current flows through a diode 904 in such a manner that the current flow through the inductor 901 continues, whereby a load capacitor 905 is charged.

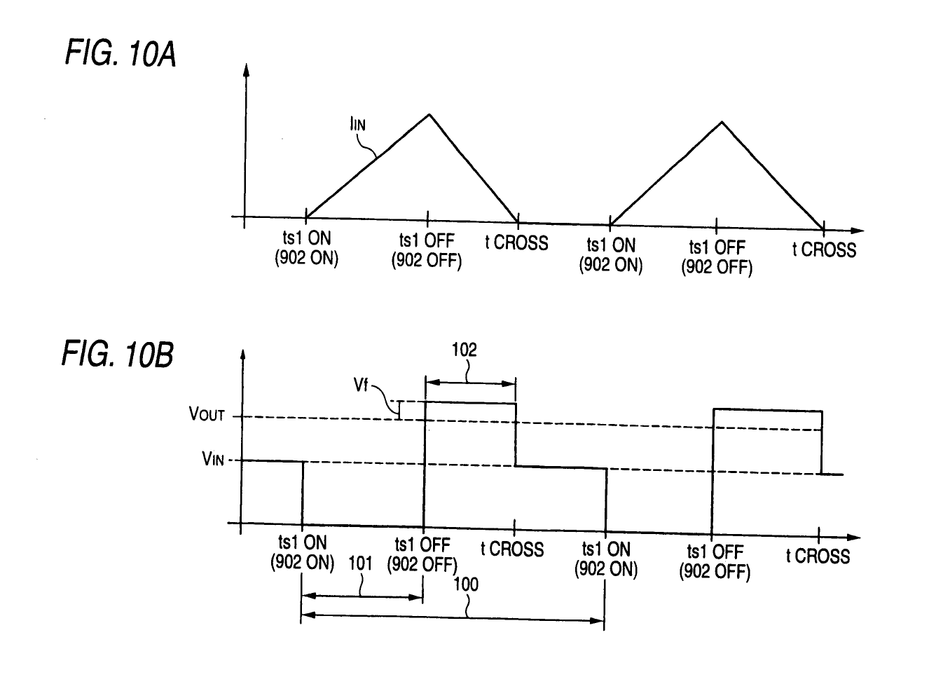

FIGS. 10(A) and 10(B) show waveforms appearing in the boost converter booster circuit of FIG. 9 in an ideal case that there are no parasitic capacitances or parasitic inductances and the reverse recovery time of the diode 904 is zero. FIG. 10(A) shows a waveform of a current Iin flowing through the inductor 901, and FIG. 10(B) shows a waveform of a voltage appearing at an output-side node 903. In a power transfer period 102 of each cycle 100, the current Iin flowing through the inductor 901 decreases linearly and reaches zero at time tcross. The ideal diode 904 is turned off immediately at time tcross and thereby prevents a flow of a return current from the load to the input power source 906. The current Iin flowing through the inductor 901 is kept at zero until the switch 902 is closed again at time tslon. Therefore, no energy transfer occurs from time tcross to tslon.

During a shunt period 101 of each cycle 100, the switch 902 is kept closed, whereby the anode terminal (node 903) of the diode 904 is grounded and no current flows through the diode 904. Instead, a shunt current (Is) flows into the inductor 901 from the power source 906 and flows through the closed switch 902. Since the circuit is assumed to be a combination of ideal components, the current Iin flowing through the inductor 901 increases linearly from zero until time tsloff when the switch 902 is opened and a new power transfer period 102 starts.

In each power transfer period 102 during which the switch 902 is opened and the load capacitor 905 is charged by a current flowing through the diode 904, input power that has been supplied from the power source (Vin) 906 flows from the inductor 901 to the load side via the diode 904 in the form of a current. The current is rectified by the diode 904 and smoothed by the capacitor 905 and converted to a DC voltage which is higher than the voltage of the power source (Vin) 906.

In the boost converter booster circuit according to the invention, the above-described inductor is not any of an inductor provided outside the semiconductor device, an inductor incorporated in the semiconductor chip, and an inductor formed by an interconnection in the semiconductor chip. Instead, it is a lead and a bonding wire of the semiconductor device which connect the external power supply source to the semiconductor chip.

### First Embodiment

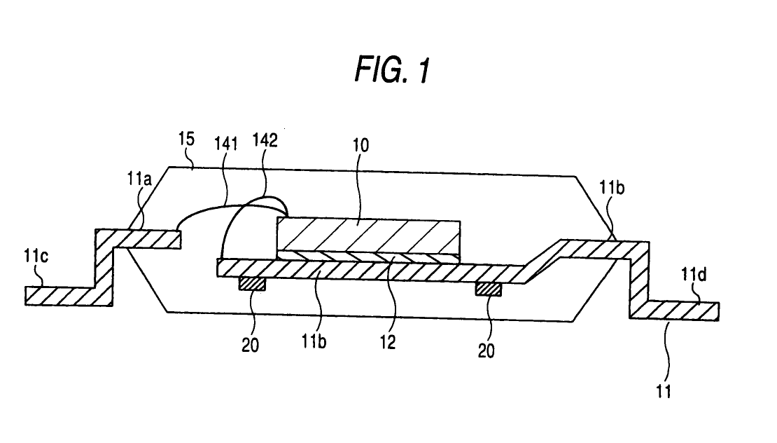

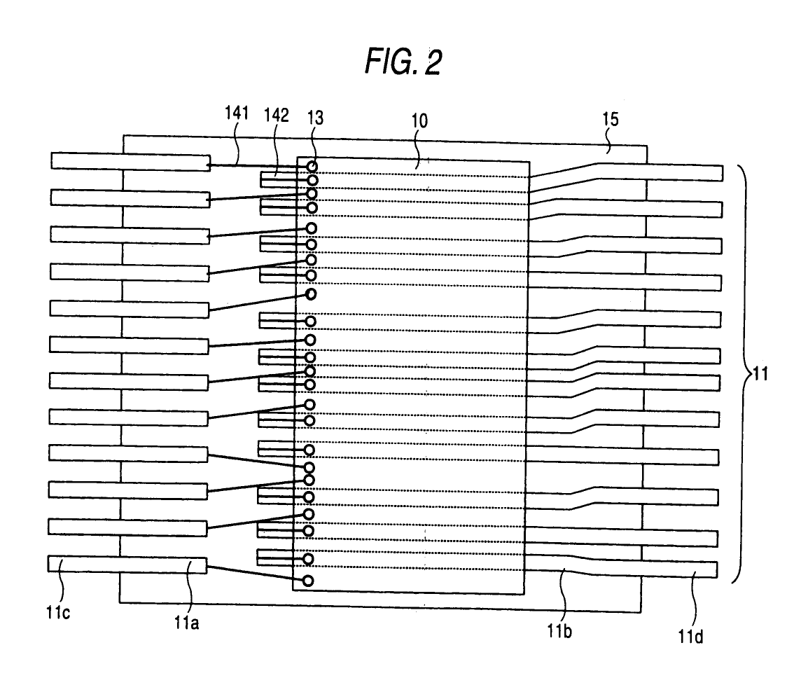

FIG. 1 is a partially sectional side view schematically showing a semiconductor device which includes a boost converter booster circuit according to a first embodiment of the invention and which is sealed in a TSOP (thin small outline package). FIG. 2 is a partially see-through plan view schematically showing the semiconductor device of FIG. 1.

A lead frame 11 has plural pairs of outer leads 11c and 11d which are opposed to each other and plural pairs of inner leads 11a and 11b which extend inward (i.e., in such a direction as to opposed to each other) from the corresponding outer leads 11c and 11d. The two sets of inner leads, that is, the inner leads 11a and the inner leads 11b, have different lengths, and the longer inner leads 11b are depressed for mounting of a semiconductor chip 10.

The semiconductor chip 10 is fixed on the depressed inner leads 11b with a thin organic insulating film 12 (made of a polyimide-type epoxy resin, for example) that is stuck to the back surface of the semiconductor chip 10. The semiconductor chip 10 is oriented so that bonding pads 13 which are arranged on the device forming surface in a concentrated manner adjacent to one chip sideline are located on the side closer to the outer leads 11c than the outer leads 11d.

The organic insulating film 12 is used for insulating the chip back surface from the die lead portion and for fixing the chip 10 on the leads 11b. As the organic insulating film 12, a film-like insulative adhesive, which is laminated on the back surface of a wafer before dicing the wafer into chips and remains left on the back surface of each chip after dicing process, can be used.

The shorter inner leads 11a on which the chip 10 is not mounted are connected to part of the bonding pads 13 by first group of bonding wires 141.

The tip portions of the longer inner leads 11b on which the chip 10 is mounted are connected to the remaining part of the bonding pads 13 by second group of bonding wires 142.

A resin 15 seals in the inner leads 11a and 11b of the lead frame, the chip 10, and the bonding wires 141 and 142 and thereby forms a resin package.

The outer leads 11c and 11d (portions of the lead frame) that are continuous with the inner leads 11a and 11b, respectively, project from at least an opposite pair of side faces of the resin package and serve as external terminals.

An external power supply source is connected to the outer lead 11d of one of the combinations of an outer lead 11d, an inner lead 11b, and a bonding wire 142 connected to the inner lead 11b. The lead and the bonding wire that are connected to the external power supply source are used as an inductor. The lead and the bonding wire that are connected to the external power source are connected to a circuit formed in the semiconductor chip 10 and serves as part of a boost converter booster circuit.

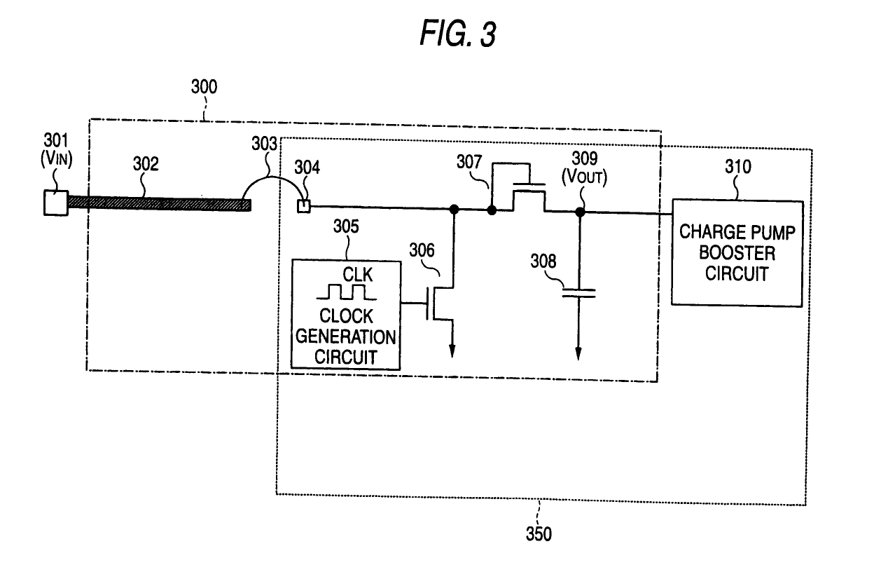

FIG. 3 shows a boost converter booster circuit in which the above-mentioned lead and bonding wire that are connected to the external power supply source are used as an inductor. The boost converter booster circuit of FIG. 3 is composed of a lead 302, a bonding wire 303, a bonding pad 304, a clock generation circuit 305, a transistor 306, a diode-connected transistor 307 which serves as a rectifier element, and a capacitor 308. The gate, drain, and source terminals of the transistor 306 are connected to the clock generation circuit 305, an external power supply source via the lead 302 and the bonding wire 303, and the ground respectively.

The external power supply source and the ground are connected via the lead and the bonding wire and disconnected repeatedly by the transistor 306 that is driven by a clock signal generated by the clock generation circuit 305. During that course, the voltage is boosted by counter-electromotive force generated by the inductance of the lead 302 and the bonding wire 303. When the transistor 306 is turned off and the external power supply source and the ground are disconnected, counter-electromotive force is generated by the energy that is stored in the electromagnetic field so that the current flowing through the inductor which consists of the lead 302 and the bonding wire 303 continues to flow. As a result, the current continues to flow via the diode-connected transistor 307 and the capacitor 308 is charged so as to produce a voltage that is higher than the input voltage. A boosted voltage 309 is supplied to a downstream charge pump booster circuit 309.

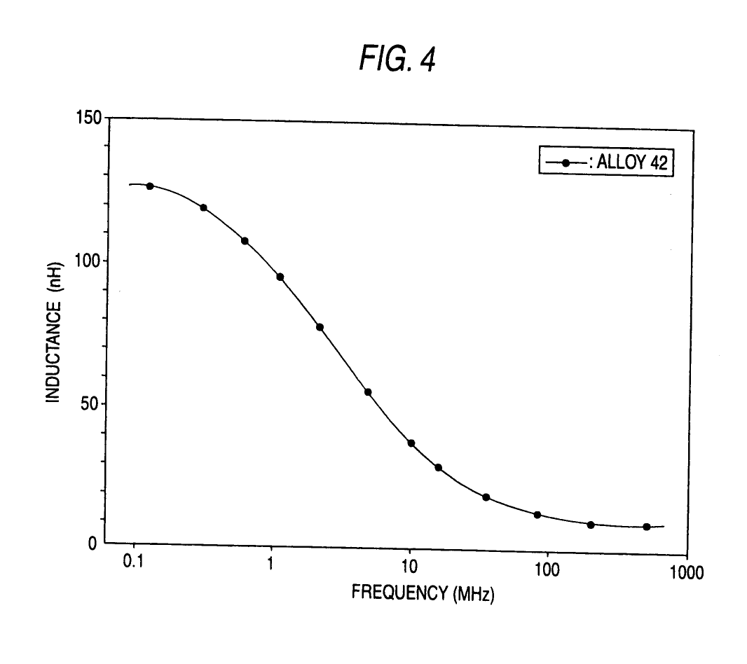

The lead 302 is made of an iron-nickel alloy capable of realizing a large inductance, such as Alloy 42 which contains nickel at 42%, whereby the boost converter booster circuit can be constructed with a shorter lead length. FIG. 4 shows a frequency vs. inductance characteristic that is obtained by using the iron-nickel alloy Alloy 42, which is widely used as a material of TSOP leads. It is seen that inductance as large as tens of nH to 100 nH is attained in a frequency range around 1 MHz because Alloy 42 is a ferromagnetic substance.

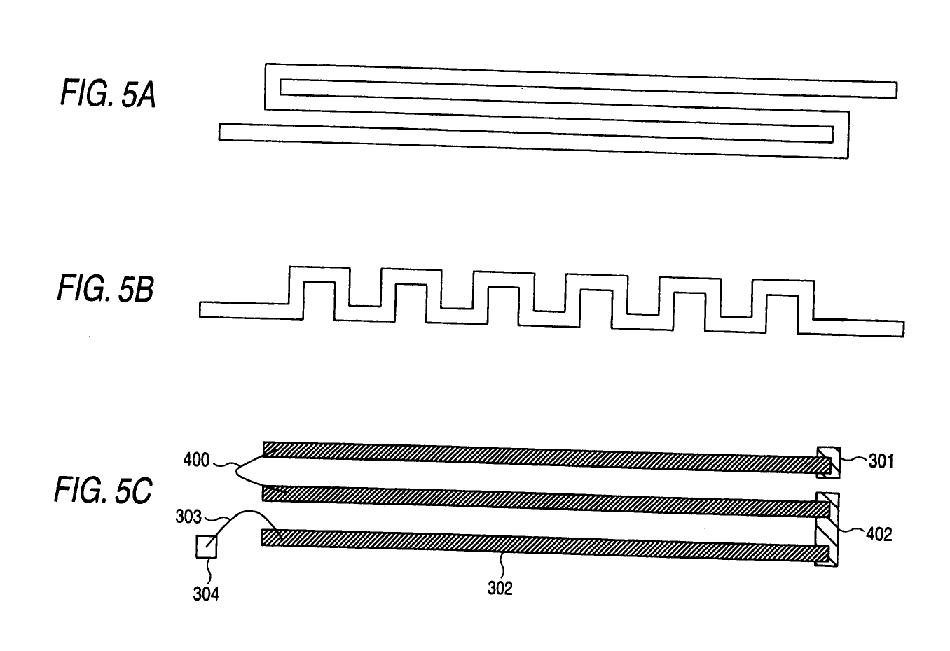

Although as described above a certain level of inductance can be attained without the need forming a special lead shape, lead shapes as shown in FIGS. 5(a) and 5(b) may be employed to increase the inductance. As a further alternative, as shown in FIG. 5(c), the inductance may be increased by connecting three leads in series by a bonding wire 400 and an outside-package interconnection 402. The interconnection 402 may be one of printed interconnections to be used when the package is mounted on a printed circuit board.

According to the first embodiment of the invention, since a high boosted voltage generated by the boost converter booster circuit which is efficient because a lead and a bonding wire of the package are used as an inductor can be supplied to the charge pump booster circuit as an input voltage, the number of boost stages can be reduced to a large extent. This makes it possible to provide a semiconductor device having a booster circuit that is higher in boost efficiency and smaller in circuit area than a conventional booster circuit having only a charge pump booster circuit. It also becomes possible to provide a semiconductor device having a booster circuit that is smaller in circuit area than a conventional boost converter booster circuit. Furthermore, the cost can be reduced because an inexpensive package having a TSOP structure in which bonding pads are arranged on one side of a semiconductor chip is used and because it is not necessary to use an inductor being an external component, incorporate an inductor in a chip, or form a spiral interconnection layer, for example, in a chip as an inductor.

### Second Embodiment

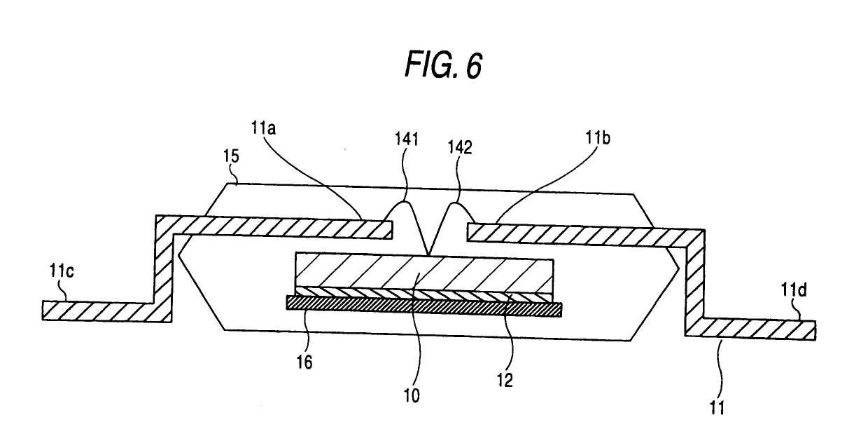

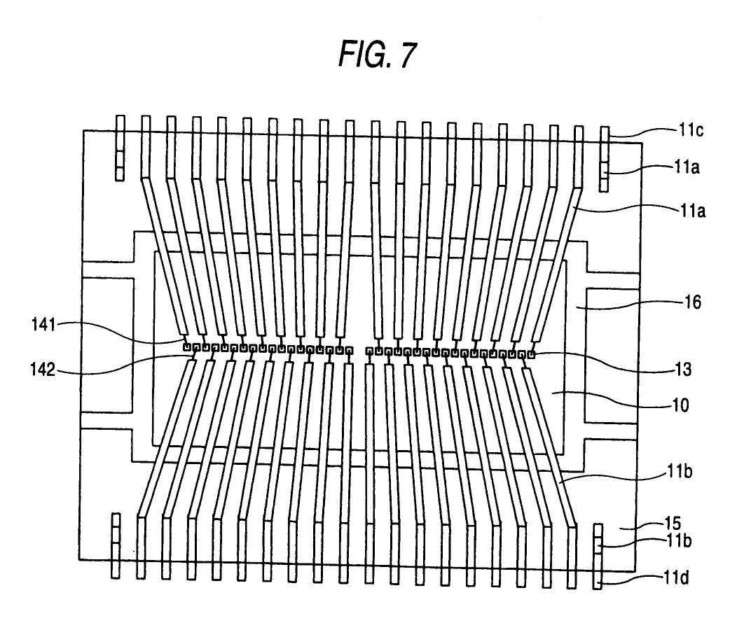

FIG. 6 is a partially sectional side view schematically showing a semiconductor device which includes a boost converter booster circuit according to a second embodiment of the invention. FIG. 7 is a partially see-through plan view schematically showing the semiconductor device of FIG. 6.

The second embodiment is different from the first embodiment in employing what is called a center pad arrangement in which bonding pads are arranged approximately along a center line. That is, according to the second embodiment of the invention, in the boost converter booster circuit 300 shown in FIG. 3, the lead 302 which is part of the inductor is one of inner leads 11a and inner leads 11b which are approximately the same in length. The other points are the same; that is, as shown in FIG. 3, the boost converter booster circuit is provided with a bonding wire 303, a bonding pad 304, a clock generation circuit 305, a transistor 306, a diode-connected transistor 307 (switching element) which serves as a rectifier element, and a capacitor 308. The gate, drain, and source terminals are connected to the clock generation circuit 305, an external power supply source via the lead 302 and the bonding wire 303, and the ground respectively. A charge pump booster circuit 310 is provided downstream of and connected to the boost converter booster circuit.

A lead frame 11 has plural pairs of outer lead 11c and 11d which are opposed to each other and plural pairs of inner leads 11a and 11b which extend inward (i.e., in such a direction as to opposed to each other) from the corresponding outer leads 11c and 11d. The two sets of inner leads, that is, the inner leads 11a and the inner leads 11b, are approximately the same in length, which is different than in the first embodiment of the invention.

In a semiconductor chip 10, bonding pads 13 which are aluminum films, for example, are arranged on the device forming surface in a concentrated manner approximately along a chip center line. And the semiconductor chip 10 is fixed on a frame lead 16 with a thin organic insulating film 12 (made of a polyimide-type epoxy resin, for example) that is stuck to the back surface of the semiconductor chip 10.

The organic insulating film 12 is used for insulating the chip back surface from the die lead portion and for fixing the chip 10 on the lead frame. As the organic insulating film 12, a film-like insulative adhesive, which is laminated on the back surface of a wafer before dicing the wafer into chips and remains left on the back surface of each chip after dicing process, can be used.

Bonding wires 141 and 142 are metal thin wires that electrically connect the bonding pads 13 which are arranged approximately along the chip center line to tip portions of two sets of inner leads, that is, the 11a inner leads and inner leads 11b (wire bonding). The bonding wires 141 and 142 are Au thin wires which are usually 20 to 30 μm in diameter at present. Wire bonding is performed by an ordinary ultrasonic pressure bonding method.

A resin 15 seals in the inner leads 11a and 11b of the lead frame, the semiconductor chip 10, and the bonding wires 141 and 142 and thereby forms a resin package. In this example, the base portions of the inner leads 11a and 11b are located approximately at the center, in the thickness direction, of the resin 15, whereby pressure balance is taken between the top and bottom resin portions during resin sealing.

The outer leads 11c and 11d (portions of the lead frame) that are continuous with the inner leads 11a and 11b, respectively, project from at least an opposite pair of side faces of the resin package and serve as external terminals.

In the semiconductor device according to the second embodiment of the invention, since the bonding pads 13 are arranged approximately along the center line of the semiconductor chip 10, each opposite pair of leads are the same in length, which is different from in the first embodiment. An external power supply source is connected to the outer lead of one of the combinations of a lead and a bonding wire connected to each other. The lead and the bonding wire that are connected to the external power supply source are used as an inductor. The lead and the bonding wire that are connected to the external power supply source are connected to a circuit formed in the semiconductor chip 10 and serves as part of a boost converter booster circuit.

The lead shapes as shown in FIGS. 5(a) and 5(b) may be employed to increase the inductance of the lead that is connected to the external power source. As a further alternative, as shown in FIG. 5(c), the inductance may be increased by connecting three leads in series by the bonding wire 400 and the outside-package interconnection 402. The interconnection 402 may be one of printed interconnections to be used when the package is mounted on a printed circuit board.

In the semiconductor device using the center-pads-type semiconductor chip according to the second embodiment of the invention, the area occupied by the semiconductor chip in the sealing resin is approximately the same as in the semiconductor device using the single-sided-pads-type semiconductor chip according to the first embodiment of the invention. However, the semiconductor device according to the second embodiment provides the following advantages.

Where a center-pads-type semiconductor chip as employed in the second embodiment of the invention in which the bonding pads are arranged approximately along the center line is used, the variation of the electrical length from the region inside the semiconductor chip to the region outside the semiconductor chip can be made smaller than in the case where a single-sided-pads-type semiconductor chip is used. The wiring length of a power line from a region inside the semiconductor chip to a region outside the semiconductor chip can be decreased and hence the voltage drop can be reduced. Employing a lead having a large inductance as the lead connected to the external power supply source makes it possible to provide a semiconductor device having a boost converter booster circuit which is low in cost, small in circuit area, and high in boost efficiency.

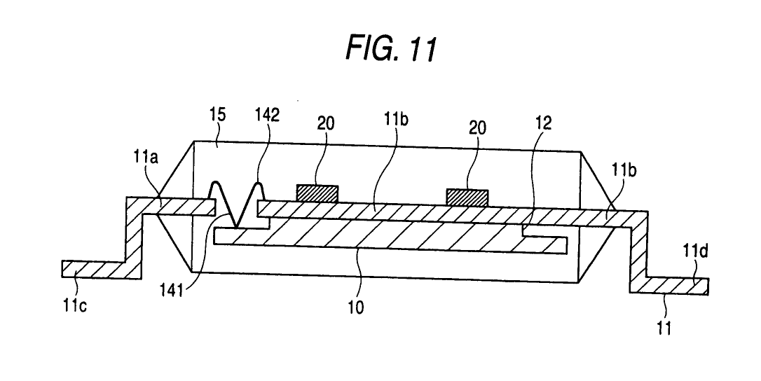

The invention is not limited to the disclosures of the above embodiments. For example, In each of the semiconductor chips 10 described in the first and second embodiments of the invention, the bonding pads are provided on the top surface of the semiconductor chip 10. Wire bonding is performed from the leads to the bonding pads provided on the top surface of the semiconductor chip 10. An alternative configuration is possible in which bonding pads are provided on the bottom surface of a semiconductor chip and wire bonding is performed from leads to the bonding pads provided on the bottom surface of the semiconductor chip. Another alternative configuration is possible in which bonding pads are provided on the top surface of a semiconductor chip and the semiconductor chip is fixed to the leads or the frame lead 16 at the top face. As shown in FIG. 11, the semiconductor device may be configured that the bonding pads are provided near an edge of the top face, and wherein the semiconductor chip is fixed to the leads by insulating adhesive at the top face.

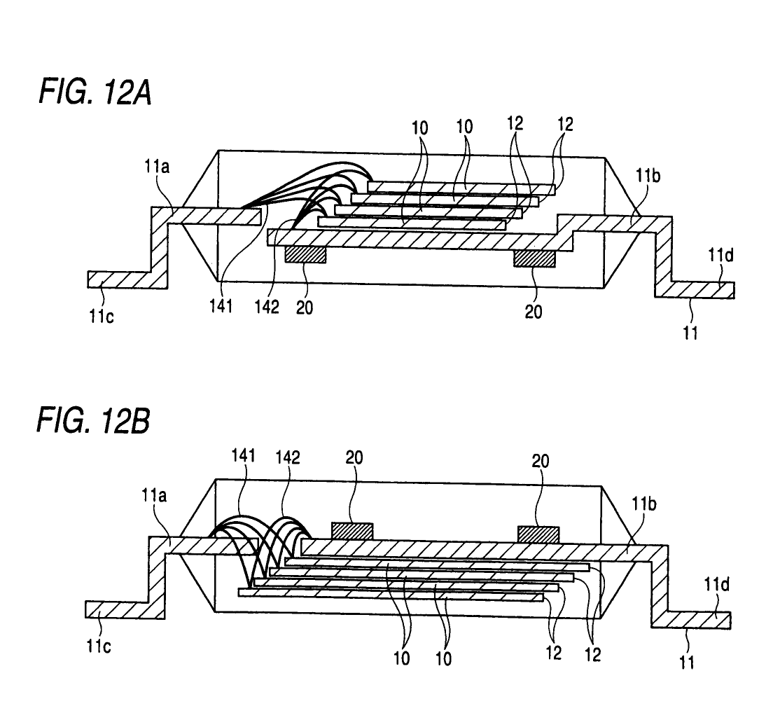

Although each of the semiconductor chips 10 described in the first and second embodiments of the invention is a single-layer chip, semiconductor chips may be stacked. In such a case, the bonding pads of each chip of a semiconductor device may be connected to leads by bonding wires as is done ordinarily. Alternatively, a semiconductor device may employ multilayered semiconductor chips in which electrical connections between the layers are established by penetrated electrodes. As shown in FIG. 12, the semiconductor device may include a chip stack that consists of a plurality of semiconductor chips, the semiconductor chips being stacked on one another with adhesive, the chip stack being sealed by resin, wherein each of the semiconductor chips includes a plurality of bonding pads arranged along one side of a top face, wherein the bonding pads of each of the semiconductor chips are connected to the leads by the bonding wires. The semiconductor device may be configured that the chip stack is fixed to the leads by insulating adhesive at a bottom face of a bottom most one of the semiconductor chip, or the chip stack is fixed to the leads by insulating adhesive at the top face of a topmost one of the semiconductor chip.

What is claimed is:

1. A semiconductor device comprising:
a semiconductor chip that is sealed in a package; and
a lead that is connected to a power supply voltage source,
wherein the semiconductor chip includes a boost converter including:
a switch that controls a connection between a first terminal connected to the lead and a second terminal connected to a ground based on a clock signal;
a rectifier having an anode terminal connected to the lead; and
a capacitor connected between a cathode terminal of the rectifier and the ground.

2. The semiconductor device according to claim 1, wherein the boost converter further includes a clock generator that generates the clock signal.

3. The semiconductor device according to claim 1, wherein the semiconductor chip further includes a charge pump that is supplied with a boosted voltage output from the boost converter.

4. The semiconductor device according to claim 1, wherein the semiconductor chip includes a plurality of bonding pads on a top face of the semiconductor chip, the bonding pads arranged along one side of the top face, and
wherein the semiconductor device further includes:
a lead frame including a first group of leads including the lead and a second group of leads opposed to the first group of leads;
a first group of bonding wires connecting the bonding pads to the first group of leads; and
a second group of bonding wires connecting the bonding pads to the second group of leads.

5. The semiconductor device according to claim 4, wherein the bonding pads are arranged at a center area of the top face, and
wherein the lead flame further includes a die pad on which the semiconductor chip is fixed by insulating adhesive.

6. The semiconductor device according to claim 1, wherein the lead is made of an alloy including Fe(iron) and Ni(Nickel).

7. The semiconductor device according to claim 3 further comprising a semiconductor memory.

8. The semiconductor device according to claim 7, wherein the semiconductor memory is supplied with a voltage output from the charge pump.

9. The semiconductor device according to claim 4,wherein the semiconductor chip is fixed to the first group of leads by insulating adhesive at a bottom face that opposes to the top face.

10. The semiconductor device according to claim 4,
wherein the semiconductor chip is fixed to the first group of leads by insulating adhesive at the top face.

11. The semiconductor device according to claim 4 further comprising a chip stack that consists of a plurality of semiconductor chips including the semiconductor chip, the semiconductor chips being stacked on one another with adhesive, the chip stack being assembled in the package,
wherein each of the semiconductor chips includes a plurality of bonding pads arranged along one side of a top face,
wherein the bonding pads of each of the semiconductor chips are connected to the first group of leads and the second group of leads by the first group of bonding wires and the second group of bonding wires.

12. The semiconductor device according to claim 11, wherein the chip stack is fixed to the first group of leads by insulating adhesive at a bottom face of the bottom most one of the semiconductor chips.

13. The semiconductor device according to claim 11, wherein the chip stack is fixed to the first group of leads by insulating adhesive at the top face of the topmost one of the semiconductor chips.

14. The semiconductor device according to claim 11, wherein the chip stack include a plurality of semiconductor chips each of which includes the boost converter.

15. The semiconductor device according to claim 14, wherein the lead is connected to each of the semiconductor chips including the boost converter.

16. The semiconductor device according to claim 14, wherein the first group of leads include a plurality of leads connected to the power supply voltage source, and
wherein each of the leads is respectively connected to each of the semiconductor chips that includes the boost converter.

17. The semiconductor device according to claim 2, wherein the clock generator adjusts a frequency or a duty ratio of the clock signal based on the voltage output from the boost converter.

18. The semiconductor device according to claim 2, wherein the clock generator generates the clock signal having a frequency lower than 10 MHz.

19. The semiconductor device according to claim 4, wherein the lead is formed to have a path that is longer than other leads in the first group of leads.

20. The semiconductor device according to claim 4, wherein the first group of leads includes a pair of extension leads that is connected with each other by a bonding wire,
wherein the lead is connected to the power supply voltage source via the pair of extension leads and via a wiring provided on a circuit board on which the semiconductor devise is mounted.
